(19) United States
(12) Patent Application Publication
(10) Pub. No.: US 2019/0131111 A1
(43) Pub. Date: May 2, 2019

(54) CHEMICAL VAPOR DEPOSITION APPARATUS AND METHOD FOR FORMING FILMS

(71) Applicant: Wuhan China Star Optoelectronics Semiconductor Display Technology Co., Ltd, Wuhan, Hubei (CN)

(72) Inventor: Rui XIE, Shenzhen, Guangdong (CN)

(21) Appl. No.: 15/742,945

(22) PCT Filed: Nov. 30, 2017
(86) PCT No.: PCT/CN2017/114082

§ 371 Date: Jan. 9, 2018

(30) Foreign Application Priority Data
Oct. 30, 2017 (CN) 201711067347.8

(51) Int. Cl. H01J 37/32; C23C 16/507; C23C 16/52

(52) U.S. Cl. CPC H01J 37/32174; H01J 37/32522; H01J 37/32577; H01J 37/3244; C23C 16/52; H01J 37/32091; C23C 16/507

(57) ABSTRACT

A chemical vapor deposition (CVD) apparatus and a method for forming films by using the CVD apparatus are provided. A conductor coil is mounted below a susceptor and connecting an alternating current, to produce an alternating magnetic field and initiate eddy current effect, for heating the susceptor. The susceptor would be heated more uniformly. At the same time the plasma above the susceptor would also be more uniform due to the alternating magnetic field acting on the plasma. Therefore, the thin film formed above the susceptor has a better homogeneity, the mura of thin films is improved, the quality of the films formed by CVD is also improved, and the yield thereof is promoted.

### RELATED APPLICATIONS

The present application is a National Phase of International Application Number PCT/CN2017/114082, filed Nov. 30, 2017, and claims the priority of China Application No. 201711067347.8, filed Oct. 30, 2017.

### FIELD OF THE DISCLOSURE

The disclosure relates to a chemical vapor deposition (CVD) technical field, and more particularly to a CVD apparatus and a method for forming films by using the CVD apparatus.

### BACKGROUND

In chemical vapor deposition (CVD) process, it is required to form films at high temperature. The heating resistance wire is mounted in the glass susceptor of the CVD apparatus to transfer heat to the glass through heating the glass susceptor. Because the temperature of heating resistance wire is higher than that of periphery, the film formed right above the heating resistance wire would be different to others when the CVD apparatus is applied to form films. In a top view, the heating resistance wire mounted on the glass susceptor has an uneven pattern shaped like a butterfly, namely mura, so the film formed above the glass susceptor also has mura like a butterfly, thereby to affect the corresponding regional electricity.

### SUMMARY

One purpose of the present invention is to provide a chemical vapor deposition (CVD) apparatus and a method for forming films by using the CVD apparatus, for improving heating uniformity of the susceptor and heating the plasma above the susceptor more uniformly, from two aspects to promote the homogeneity of the film formed by the CVD apparatus, improve the mura of thin film, and increase the electricity stability of products finally.

For realizing the above purpose, the present invention provides a CVD apparatus comprising a first electrode plate and a second electrode plate arranged in parallel, wherein the first electrode plate is connected to a radio frequency power supply, and the second electrode plate is connected to ground; a basal body for loading a thin film formed by CVD, wherein the basal body is disposed between the first electrode plate and the second electrode plate; and a coil carrier, disposed below the basal body, wherein the coil carrier has a conductor coil thereon.

Optionally, the second electrode plate is loading the basal body, and a surface of the basal body far away the second electrode plate is facing the first electrode plate and loading the thin film formed by CVD.

Optionally, a current of the conductor coil is about 0.1 to 5 Amp.

Optionally, a magnetic field strength of the conductor coil is about 0.001 to 100 Tesla.

Optionally, the current is an alternating current, and an alternating frequency of an alternating magnetic field produced by the alternating current is about 50 to 2000 Hertz.

Optionally, a length of the coil carrier is larger than or equal to a length of the basal body, and a length of the conductor coil is larger than or equal to a length of the basal body.

Optionally, the CVD apparatus further comprises a susceptor. The first electrode plate and the second electrode plate are arranged in parallel from left to right and disposed facing each other, the basal body is disposed on the susceptor, the susceptor is disposed below the first electrode plate and the second electrode plate, and the coil carrier is disposed below the susceptor.

Optionally, the conductor coil includes two parts disposed separately on two opposite sides of the coil carrier, and the two parts have opposite polarity.

The present invention also provides a method for forming films by using the above CVD apparatus. The method comprises disposing the first electrode plate and the second electrode plate in a vacuum environment; supplying an alternating current to the conductor coil disposed on the coil carrier; producing a radio frequency electric field between the first electrode plate and the second electrode plate; and supplying process gases for forming films between the first electrode plate and the second electrode plate.

The present invention further provides another method for forming films by using the above CVD apparatus. The method comprises disposing the first electrode plate and the second electrode plate in a vacuum environment; producing a radio frequency electric field between the first electrode plate and the second electrode plate; supplying an alternating current to the conductor coil disposed on the coil carrier; and supplying process gases for forming films between the first electrode plate and the second electrode plate.

The present invention provides the chemical vapor deposition (CVD) apparatus and the method for forming films by using the CVD apparatus. The conductor coil is mounted below the susceptor and connecting an alternating current, to produce an alternating magnetic field and initiate eddy current effect, for heating the susceptor. The susceptor would be heated more uniformly. At the same time the plasma above the susceptor would also be more uniform due to the alternating magnetic field acting on the plasma. Therefore, the thin film formed above the susceptor has a better homogeneity, the mura of thin films is improved, the quality of the films formed by CVD is also improved, and the yield thereof is promoted.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structure view illustrating the CVD apparatus in the first embodiment provided by the present invention;

FIG. 2 is a scheme view illustrating the alternating magnetic field produced in the space around the basal body after the conductor coil is connecting with an alternating current in the first embodiment;

FIG. 3 is a structure view illustrating the CVD apparatus in the second embodiment provided by the present invention;

FIG. 4 is a scheme view illustrating the alternating magnetic field produced in the space around the basal body after the conductor coil is connecting with an alternating current in the second embodiment; and

FIG. 5 is a flow chart illustrating the method for forming films by using the CVD apparatus of the present invention.

The implementation of the purpose, functional features and advantages of the present invention would be further illustrated combined with the embodiments and drawings.

### DETAILED DESCRIPTION OF PREFERRED EMBODIMENTS

It should be noted, the embodiments illustrated herein are applied for explaining rather than limiting the present invention.

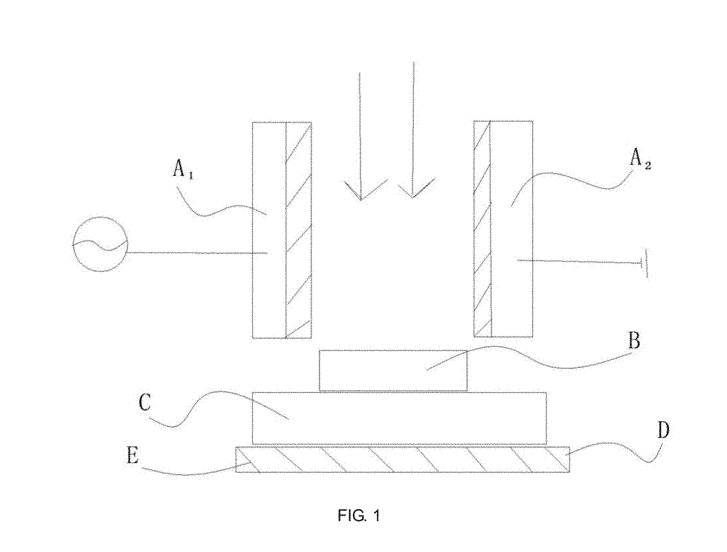

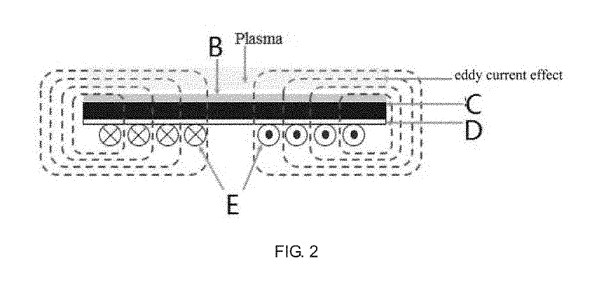

Please refer to FIG. 1 and FIG. 2, in a first embodiment of the present invention, a chemical vapor deposition (CVD) apparatus is provided, for improving the mura of thin film formed by the CVD process. The CVD apparatus comprises a first electrode plate A1 and a second electrode plate A2 and a basal body B. The first electrode plate A1 and the second electrode plate A2 are arranged in parallel. The first electrode plate A1 is connected to a radio frequency power supply, and the second electrode plate A2 is connected to ground. The basal body B for loading a thin film formed by CVD is disposed between the first electrode plate A1 and the second electrode plate A2. The CVD apparatus further comprises a susceptor C. The first electrode plate A1 and the second electrode plate A2 are arranged in parallel from left to right and facing each other. The basal body B is disposed on the susceptor C, and the susceptor C is disposed below the first electrode plate A1 and the second electrode plate A2. In this embodiment, the basal body B is made of glass material. It is understandable, FIG. 1 is a structure view of the CVD apparatus for easy understanding, the actual structure of CVD apparatus is more complicated and finer than that shown in the drawings herein.

Please refer to FIG. 1 and FIG. 2, the CVD apparatus further comprises a coil carrier D. The coil carrier D is disposed below the susceptor C. A conductor coil E is disposed above the coil carrier D, for example, mounted in the coil carrier D or disposed on one surface of the coil carrier D far away the susceptor C. The coil carrier D is a conductor. The distance between the coil carrier D and the susceptor C is preferably about 1 mm to 200 mm. The current of the conductor coil E is preferably about 0.1 to 5 Amp. The magnetic field strength of the conductor coil E is preferably about 0.001 to 100 Tesla.

The current is an alternating current. When the conductor coil E is connecting with the alternating current, an alternating magnetic field is produced by the alternating current, and the alternating frequency of the alternating magnetic field caused by the alternating current is about 50 to 2000 Hertz. The alternating magnetic field would initiate eddy current effect occurring inside the conductor coil E, and simultaneously initiate eddy current effect occurring inside the coil carrier D, thereby to generate and transfer heat to the susceptor C and the basal body B. The heat generated by eddy current effect would make all areas of the susceptor C and all areas of the basal body B be heated uniformly.

The length of the coil carrier D is larger than or equal to that of the basal body B, and the length of the conductor coil E is larger than or equal to that of the basal body B. Thus, when the conductor coil E is connecting with the alternating current, the alternating magnetic field produced by the alternating current could cover whole basal body B, to further ensure all areas of the basal body B to be heated uniformly.

In an embodiment, the conductor coil E includes two parts disposed separately on two opposite sides of the coil carrier D, and the two parts have opposite polarity.

In an embodiment, the first electrode plate A1 could be combined with a magnetic field coil, and at the same time the second electrode plate A2 could be combined with another magnetic field coil. When the CVD apparatus is in operation, the two magnetic field coils would generate a magnetic field to make the plasma flowing between the first electrode plate A1 and the second electrode plate A2 be more uniform.

It is understandable, for guaranteeing the quality of films, the film process above the basal body B is performed in vacuum environment. Therefore, the CVD apparatus further includes a chamber (not shown in drawings) for receiving the first electrode plate A1, the second electrode plate A2, the basal body B, the susceptor C and the coil carrier D. The chamber has an entrance for injecting the process gases. The chamber also has an extraction port for exhausting the air therein to have the vacuum environment in the chamber.

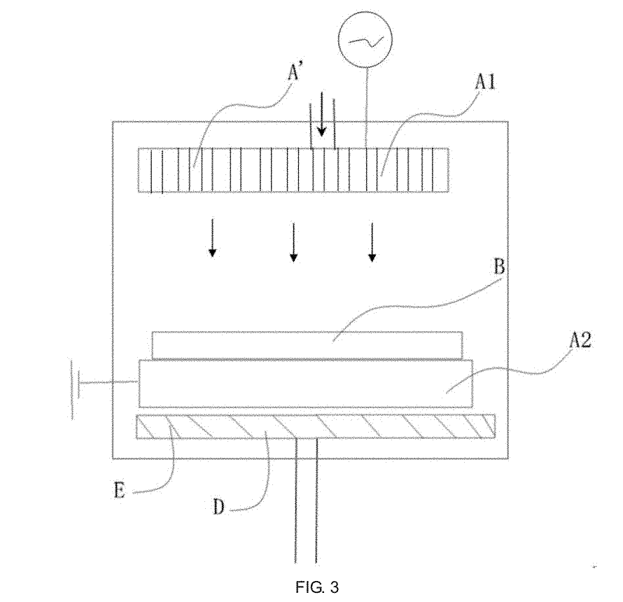

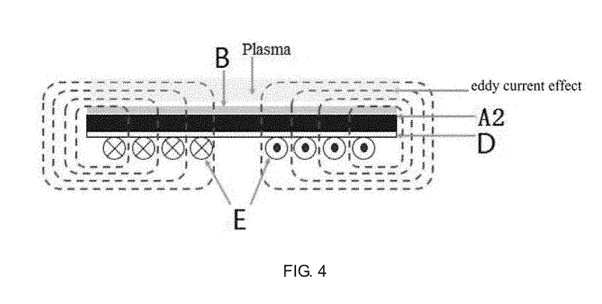

Please refer to FIG. 3 and FIG. 4, the second embodiment of the present invention is illustrated. For the convenience of description, the same names of elements in this embodiment are labeled with the same number as illustrated in the first embodiment. However, it does not mean the elements with the same number must be the identical elements. The CVD apparatus in the second embodiment comprises a first electrode plate A1, a second electrode plate A2, a basal body B, a coil carrier D and a conductor coil E. The first electrode plate A1 is connected to a radio frequency power, and the second electrode plate A2 is connected to ground.

The basal body B is disposed between the first electrode plate A1 and the second electrode plate A2. In specific, the second electrode plate A2 is loading the basal body B, and one side of the basal body B facing the first electrode plate A1 is applied to form films. The first electrode plate A1 includes multiple through holes A′ thereon. The process gases for forming films are entering the space between the first electrode plate A1 and the second electrode plate A2 via the through holes A′, and are excited to form the plasma. The plasma would attach on the surface of the basal body B or react with the surface of a substrate to form thin films on the basal body B.

The coil carrier D is disposed on one side of the second electrode plate A2 far away the basal body B. The conductor coil E is disposed on the coil carrier D, for example, is mounted in the coil carrier D or disposed on one side of the coil carrier D far away the second electrode plate A2. When the conductor coil E is connecting with an alternating current, an alternating magnetic field is produced by the alternating current, and the alternating magnetic field would initiate eddy current effect occurring inside the conductor coil E, and simultaneously initiate eddy current effect occurring inside the coil carrier D, thereby to generate and transfer heat to the basal body B. The heat generated by eddy current effect would make all areas of the basal body B be heated uniformly.

In an embodiment, the conductor coil E includes two parts disposed separately on two opposite sides of the coil carrier D, and the two parts have opposite polarity.

It is understandable, for guaranteeing the quality of films, the film process above the basal body B is performed in vacuum environment. Therefore, the CVD apparatus further includes a chamber (not shown in drawings) for receiving the first electrode plate A1, the basal body B, the second electrode plate A2, the coil carrier D and the conductor coil E. The chamber has an entrance for injecting the process gases. The chamber also has an extraction port for exhausting the air therein to have the vacuum environment in the chamber. Besides, below the coil carrier D could be disposed a cylinder supporting unit (not shown in drawings), thereby to drive the coil carrier D, the basal body B and the second electrode plate A2 above the coil carrier D to move up and down.

The CVD apparatus in above embodiments may be the plasma enhanced chemical vapor deposition (PECVD) apparatus. The PECVD apparatus could be applied to form the thin films such as silicon nitride films, silicon monoxide films, silicon dioxide films, amorphous silicon films, silicon carbide films, solar energy materials films, diamond films, optical films, conducting metal films, carbon nanotubes films, etc. The PECVD apparatus is preferably applied to fabricate the gate, the channel, the source and the drain of a thin film transistor in display, such as the LCD or the OLED.

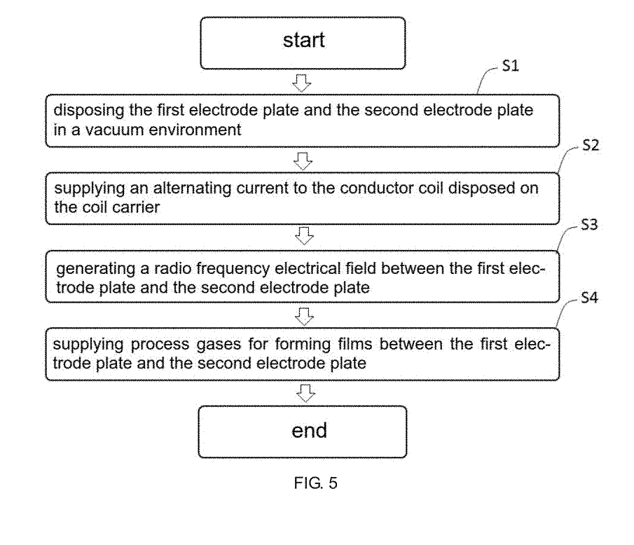

Please refer to FIG. 5, a method for forming films by using the CVD apparatus provided by the present invention comprises the following steps.

Step S1 is disposing the first electrode plate A1 and the second electrode plate A2 in a vacuum environment.

Step S2 is supplying an alternating current to the conductor coil E disposed on the coil carrier D.

The current of the conductor coil E is preferably about 0.1 to 5 Amp. The alternating current would produce an alternating magnetic field and initiate eddy current effect for heating continuously the basal body B.

Step S3 is generating a radio frequency electrical field between the first electrode plate A1 and the second electrode plate A2.

Step S4 is supplying process gases for forming films between the first electrode plate A1 and the second electrode plate A2. The radio frequency electrical field can excite the process gases to form the plasma. The plasma would recombine with a chemical reaction to deposit the resultant on the surface of the basal body B for forming the thin film.

In other embodiments, Step S2 and Step S3 could be exchanged.

In the present invention, the conductor coil is mounted below the susceptor, such as the susceptor C shown in FIG. 1 or the second electrode plate A2 shown in FIG. 3, to produce an alternating magnetic field and initiate eddy current effect, for heating the susceptor. The susceptor would be heated more uniformly. At the same time the plasma above the susceptor would also be more uniform due to the alternating magnetic field acting on the plasma. Therefore, the thin film formed by CVD above the susceptor has a better homogeneity, the mura of the thin films formed by CVD could be improved, the quality of the films formed by CVD could also be improved, and the yield thereof could be promoted.

It should be noted that, in this disclosure, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

In the description of the present invention, the terms for indicating orientations or positional relationships such as “on”, “beneath”, “above”, “below”, “left and right” for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure.

The sequence numbers of the embodiments of the invention are only for the descriptive purpose rather than represent the relative merits of the embodiments.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A chemical vapor deposition (CVD) apparatus, comprising:
a first electrode plate and a second electrode plate arranged in parallel, wherein the first electrode plate is connected to a radio frequency power supply, and the second electrode plate is connected to ground;
a basal body for loading a thin film formed by CVD, wherein the basal body is disposed between the first electrode plate and the second electrode plate; and
a coil carrier, disposed below the basal body, wherein the coil carrier has conductor coil thereon.

2. The CVD apparatus according to claim 1, wherein the second electrode plate is loading the basal body, and a surface of the basal body far away the second electrode plate is facing the first electrode plate and loading the thin film formed by CVD.

3. The CVD apparatus according to claim 1, wherein a current of the conductor coil is about 0.1 to 5 Amp.

4. The CVD apparatus according to claim 3, wherein a magnetic field strength of the conductor coil is about 0.001 to 100 Tesla.

5. The CVD apparatus according to claim 4, wherein the current is an alternating current, and an alternating frequency of an alternating magnetic field produced by the alternating current is about 50 to 2000 Hertz.

6. The CVD apparatus according to claim 1, wherein a length of the coil carrier is larger than or equal to a length of the basal body, and a length of the conductor coil is larger than or equal to a length of the basal body.

7. The CVD apparatus according to claim 1, further comprising a susceptor, wherein the first electrode plate and the second electrode plate are arranged in parallel from left to right and disposed facing each other, the basal body is disposed on the susceptor, the susceptor is disposed below the first electrode plate and the second electrode plate, and the coil carrier is disposed below the susceptor.

8. The CVD apparatus according to claim 1, wherein the conductor coil includes two parts disposed separately on two opposite sides of the coil carrier, and the two parts have opposite polarity.

9. A method for forming films by using the CVD apparatus according to claim 1, comprising:
disposing the first electrode plate and the second electrode plate in a vacuum environment;
supplying an alternating current to the conductor coil disposed on the coil carrier;
producing a radio frequency electric field between the first electrode plate and the second electrode plate; and
supplying process gases for forming films between the first electrode plate and the second electrode plate.

10. A method for forming films by using the CVD apparatus according to claim 1, comprising:
disposing the first electrode plate and the second electrode plate in a vacuum environment;
producing a radio frequency electric field between the first electrode plate and the second electrode plate;
supplying an alternating current to the conductor coil disposed on the coil carrier; and
supplying process gases for forming films between the first electrode plate and the second electrode plate.

11. The method for forming films according to claim 9, wherein the second electrode plate is loading the basal body, and a surface of the basal body far away the second electrode plate is facing the first electrode plate and loading the thin film formed by CVD.

12. The method for forming films according to claim 9, wherein a current of the conductor coil is about 0.1 to 5 Amp.

13. The method for forming films according to claim 12, wherein a magnetic field strength of the conductor coil is about 0.001 to 100 Tesla.

14. The method for forming films according to claim 13, wherein the current is an alternating current, and an alternating frequency of an alternating magnetic field produced by the alternating current is about 50 to 2000 Hertz.

15. The method for forming films according to claim 10, wherein the second electrode plate is loading the basal body, and a surface of the basal body far away the second electrode plate is facing the first electrode plate and loading the thin film formed by CVD.

16. The method for forming films according to claim 10, wherein a current of the conductor coil is about 0.1 to 5 Amp.

17. The method for forming films according to claim 16, wherein a magnetic field strength of the conductor coil is about 0.001 to 100 Tesla.

18. The method for forming films according to claim 17, wherein the current is an alternating current, and an alternating frequency of an alternating magnetic field produced by the alternating current is about 50 to 2000 Hertz.
